(19) United States
(12) Patent Application Publication
(10) Pub. No.: US 2015/0124382 A1
(43) Pub. Date: May 7, 2015

(54) DISPLAY DEVICE AND METHOD FOR PRODUCING SAME

(71) Applicants: Akira Taniguchi, Hyogo (JP); Masaaki Ofuji, Osaka (JP); Eiichi Uriu, Osaka (JP); Kenji Hasegawa, Osaka (JP)

(72) Inventors: Akira Taniguchi, Hyogo (JP); Masaaki Ofuji, Osaka (JP); Eiichi Uriu, Osaka (JP); Kenji Hasegawa, Osaka (JP)

(73) Assignee: Panasonic Intellectual Property Management Co., Ltd., Osaka-shi, Osaka (JP)

(21) Appl. No.: 14/407,357

(22) PCT Filed: Jun. 14, 2012
(86) PCT No.: PCT/JP2012/003903

§ 371 Date: Dec. 11, 2014

(51) Int. Cl. H05K 5/03; H01J 9/26; H01J 17/49; G02F 1/1333; G02F 1/1335

(52) U.S. Cl. CPC H05K 5/03; G02F 1/133308; G02F 1/133528; H01J 17/49; H01J 9/261; G02F 2001/133331
USPC 361/679.01; 445/25

(57) ABSTRACT

A display device includes: a display panel for displaying images; a transparent protective member for protecting a display surface of the display panel; an adhesive layer that is disposed between the display panel and the transparent protective member so as to bond the display panel and the transparent protective member together; and an adjacent layer that is disposed adjacent to the adhesive layer and between the display panel and the adhesive layer or between the transparent protective member and the adhesive layer. The outer boundary of the adhesive layer lies beyond the outer boundary of the adjacent layer, as viewed from the front of the display surface of the display panel.

### TECHNICAL FIELD

The present invention relates to a display device and a method for producing the same.

### BACKGROUND ART

Recently, there has been an increasing demand for display devices such as flat screen televisions not only with higher image quality and higher reliability but also with better design. For example, the recent growing trend of display devices is a design in which the entire front surface of a display device is covered with a single cover glass (i.e., a frameless glass cover design).

This frameless glass cover design can be achieved, for example, by a first method (for example, JP 2009-296105 A) in which a cover glass is placed in front of a display surface of a display panel for displaying images, with a space (air gap) interposed between the display surface and the cover glass, and the cover glass is fixed to the display panel by means of a mounting structure such as a cabinet, or by a second method (for example, JP 2007-207841 A) in which a cover glass is attached to a display surface of a display panel with a layer made of an adhesive material (a tacky, pressure-sensitive adhesive layer or a joining layer) interposed therebetween.

In the case of the first method, the presence of the air gap increases the reflecting interfaces, which may cause image degradation such as image reflection or may narrow the viewing angle.

On the other hand, in the case of the second method, no air gap is formed. Therefore, the image degradation caused by the increase in the reflecting interfaces can be reduced by selecting as appropriate an adhesive material having a refractive index almost equal to that of the cover glass. Even if the cover glass and the display panel are warped and deformed by heat or the like, the presence of the adhesive layer or the joining layer between the cover glass and the display panel suppresses occurrence of interference fringes. This structure also makes it easier to reduce the thickness of the device. For these reasons, the structure formed (by the second method) using an adhesive layer or a joining layer can be seen as advantageous for a structure for achieving the frameless glass cover design.

Examples of the method of bonding a cover glass and a display panel together using an adhesive layer or a joining layer include a method using an ultraviolet-curable photoelastic resin (such as a UV resin or a UV adhesive material) and a method using an adhesive sheet. In the method using an ultraviolet-curable photoelastic resin, complex equipment is needed to use a liquid material in the production process and there is a risk that a chemical reaction (polymerization reaction) may occur during the production process. On the other hand, in the method using an adhesive sheet, the production process is a dry process involving no reaction system, and therefore stable production can be ensured. In addition, the production can be performed as an extension of the technique of direct attachment of film filters in the production of large plasma display panels. In this method, a material roll formed by winding in a roll shape an adhesive sheet attached to a carrier film (separator film) is usually used. The adhesive sheet is fed from the material roll and die-cut into smaller pieces having a predetermined shape. Each of the adhesive sheets thus obtained is attached to a predetermined region of a cover glass or a display panel. In this method, however, since the adhesive sheet fed from the material roll is die-cut into smaller pieces, a considerable portion of the material roll is discarded as waste and the material yield is very low. In addition, since this die cutting step is essential, the number of steps is large and the productivity is low. Furthermore, since the size of the adhesive sheets obtained by die cutting increases as the area of the display devices increases, the adhesive sheets become more difficult to handle accordingly. As a result, not only it is very difficult to handle the adhesive sheet when the sheet is attached to the cover glass or the display panel, but also the sheet is more susceptible to damage such as dents, creases, and defective edges when the sheet is handled, and these defects of the sheet are more likely to cause the defects of the product.

On the other hand, there is an option to use, as an adhesive layer, the adhesive sheet fed from the material roll as it is without being die-cut. However, in this method, since the entire material roll is used as adhesive layers for the products, the resulting adhesive layers may have, in addition to the defects of the material roll, defects caused by slitting the roll, and poor adhesion of the adhesive material of the slitted surface or adhesion of foreign substances to the slitted surface due to contact and/or abrasion with other substances during packaging, transportation, and/or use. Defects may occur when the adhesive sheet is cut for use. These defects may adversely affect the performance of the products.

As described above, it has been difficult to produce, with high yield and high productivity, a display device with high image quality, high reliability, and good design like a frameless glass cover design by using a material like an adhesive sheet.

### SUMMARY OF INVENTION

In one aspect of the present invention, a display device includes: a display panel for displaying images; a transparent protective member for protecting a display surface of the display panel; an adhesive layer that is disposed between the display panel and the transparent protective member so as to bond the display panel and the transparent protective member together; and an adjacent layer that is disposed adjacent to the adhesive layer and between the display panel and the adhesive layer or between the transparent protective member and the adhesive layer. An outer boundary of the adhesive layer lies beyond an outer boundary of the adjacent layer and within an outer boundary of the display panel and an outer boundary of the transparent protective member, as viewed from the front of the display surface of the display panel.

In one aspect of the present invention, a method for producing a display device includes the steps of: (I) preparing a display panel for displaying images, a transparent protective member for protecting a display surface of the display panel, and a material roll formed by winding in a roll shape an adhesive sheet used to bond the display panel and the transparent protective member together or the adhesive sheet formed in a predetermined shape; (II) attaching the adhesive sheet fed from the material roll or the adhesive sheet formed in the predetermined shape to the display panel or the transparent protective member; (III) forming an adjacent layer on the transparent protective member or the display panel to which the adhesive sheet has not been attached in the step (II); and (IV) bonding together the display panel or the transparent protective member to which the adhesive sheet has been attached and the transparent protective member or the display panel on which the adjacent layer has been formed so that the adhesive sheet and the adjacent layer are in contact with each other. The adhesive sheet is attached to the display panel or the transparent protective member so that an outer boundary of the adhesive sheet lies beyond an outer boundary of the adjacent layer and within an outer boundary of the display panel and an outer boundary of the transparent protective member, as viewed from the front of the display surface of the display panel.

### BRIEF DESCRIPTION OF DRAWINGS

FIG. 1A is a plan view of a display device according to an embodiment of the present invention, as viewed from the front of the display surface of the device.

FIG. 1B is a cross-sectional view schematically showing the peripheral portion of the display device shown in FIG. 1A.

FIG. 2A is a plan view of a plasma display device as an example of the display device according to the embodiment of the present invention, as viewed from the front of the display surface of the device.

FIG. 2B is a cross-sectional view schematically showing the peripheral portion of the plasma display device shown in FIG. 2A.

FIG. 3A is a plan view schematically showing a liquid crystal display device as another example of the display device according to the embodiment of the present invention, as viewed from the front of the display surface of the device.

FIG. 3B is a cross-sectional view schematically showing the peripheral portion of the liquid crystal display device shown in FIG. 3A.

FIG. 4 is a schematic diagram showing an example of the step of attaching an adhesive sheet to an object in the method for producing the display device according to the embodiment of the present invention.

### DESCRIPTION OF EMBODIMENTS

Hereinafter, an embodiment of the present invention will be described with reference to the drawings. The following embodiment is merely exemplary and is not intended to limit the present invention.

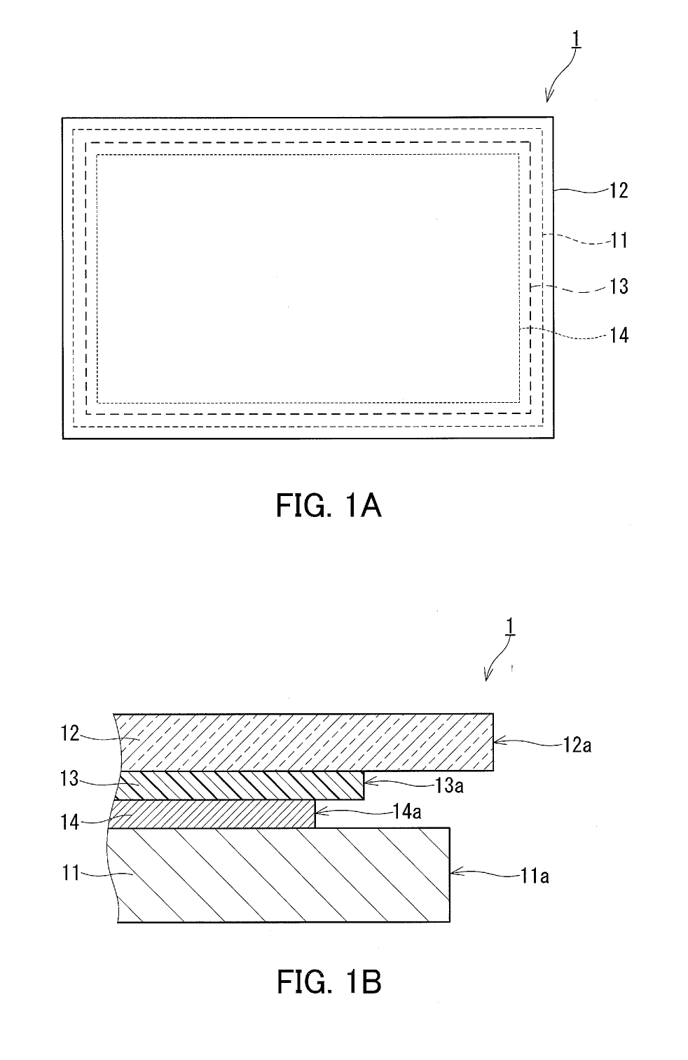

FIG. 1A is a plan view of a display device 1 according to an embodiment of the present invention, as viewed from the front of the display surface of the device. FIG. 1B is a schematic cross-sectional view of the peripheral portion of the display device 1 shown in FIG. 1A, as viewed vertically or transversely.

The display device 1 includes a display panel 11 for displaying images and a transparent protective member 12 for protecting a display surface of the display panel 11. The display device 1 further includes an adhesive layer 13 that is disposed between the display panel 11 and the transparent protective member 12 so as to bond the display panel 11 and the transparent protective member 12 together. The display device 1 further includes an optical film (adjacent layer) 14 that is disposed between the display panel 11 and the adhesive layer 12. In the present embodiment, the optical film 14 is disposed on the display surface of the display panel 11 and in contact with the adhesive layer 13.

As shown in FIG. 1A and FIG. 1B, the display device 1 of the present embodiment has a configuration in which the display panel 11 and the transparent protective member 12 are bonded together with the adhesive layer 13 but without an air gap interposed therebetween. Therefore, the display device 1 has no defects such as image degradation resulting from refractions and reflections caused by the presence of the air gap between the display panel 11 and the transparent protective member 12 and appearance of Newton's rings caused by the warpage and deformation of the transparent protective member 12. Furthermore, the display device 1 can be made thinner by the thickness of the air gap because of the absence of the air gap. The display device 1 can also have a good design because it does not need a mounting structure such as a cabinet for holding the transparent protective member 12 in the display panel 11.

The display device 1 may include a frame (not shown) for supporting the display panel 11, a back cover (not shown) disposed on the opposite side to the display surface of the display panel 11, etc., if necessary.

In the display device 1, the adhesive layer 13 is provided so that the outer boundary 13a of the adhesive layer 13 lies beyond the outer boundary 14a of the optical film 14 and within the outer boundary 11a of the display panel 11 and the outer boundary 12a of the transparent protective member 12. That is, in the end surface formed by the outer edge of the adhesive layer 13 and the outer edge of the optical film 14, the outer boundary 13a of the adhesive layer 13 extends outwardly and the outer boundary 12a of the optical film 14 adjacent to the adhesive layer 13 recedes inwardly so as to form a step therebetween. Many defects of the adhesive layer 13 occur at its edge portion. This is because a tacky adhesive sheet is usually used to form the adhesive layer 13. According to the configuration of the present embodiment, even if the adhesive layer 13 has a defect at its edge portion, the defect is received by the space (accommodated in the space) formed by the step between the outer boundary 13a of the adhesive layer 13 and the outer boundary 14a of the adjacent optical film 14. Therefore, the defective area does not overlap the optical film 14. As a result, adhesion failure does not occur, and thus product defects do not occur. The defects at the edge portion of the adhesive layer 13 include defects that may occur when an adhesive sheet is used to form the adhesive layer 13, for example, defects caused by oozing of an adhesive material that may occur at the end face of the adhesive sheet and defects caused by adhesion of substances such as dust in the environment to the end face of the adhesive sheet.

The display panel 11 has a display surface. The display surface has an effective image region in which video images to be presented to viewers are displayed and a peripheral region around the effective image region. Electrodes, sealing members, etc. are arranged in the peripheral region. In order to block electromagnetic waves from the electrodes arranged in the peripheral region, for example, the peripheral portion of the transparent protective member 12 may be painted black. As the display panel 11, for example, a plasma display panel (PDP), a liquid crystal display (LCD) panel, an organic EL (Electro-Luminescence) panel, or the like can be used. The area of the display panel 11 is not particularly limited. In the display device of the present embodiment, the larger the area of the display panel is, the greater the effect obtained is. The reason for this is as follows. In conventional production methods, it is very difficult to produce a display device with high image quality and high reliability using a large area display panel. In contrast, the display device of the present embodiment can be produced as a display device with high image quality and high reliability by a highly productive method using a later-described material roll formed by winding an adhesive sheet in a roll shape as it is.

The transparent protective member 12 is larger than the display panel 11. The outer boundary 12a of the transparent protective member 12 extends outwardly beyond the outer boundary 11a of the display panel 11, as viewed from the front of the display surface of the display panel 11. The transparent protective member 12 is a member made of a material having transparency. It is, for example, a panel made of glass. The transparent protective member 12 transmits video images displayed on the display panel 11. The transparent protective member 12 covers substantially the entire display surface of the display device 1. The material of the transparent protective member 12 is not limited to glass. Any material having transparency and suitable for protection use can be used as the material of the transparent protective member 12. For example, materials having a visible light transmittance of 85% or more, a haze value of 2% or less, and a refractive index of 1.4 to 1.6, as optical properties, are desirably used. These optical properties are merely exemplary, and it is also possible to use a colored material to adjust the transmittance, color tone, etc., as appropriate, depending on the intended use and purpose. Examples of the materials that can be used for the transparent protective member 12 include glass materials in general such as soda lime glass, thermally tempered glass, and chemically tempered glass, touch panels, and transparent resin materials such as polymethylmethacrylate (PMMA) and polycarbonate (PC). The other properties such as the thickness and elastic modulus of the transparent protective member 12 are not particularly limited because they can be selected, as appropriate, according to the selected material and the intended use and purpose of the transparent protective member 12.

The optical film 14 is disposed on the display surface of the display panel 11. As the optical film 14, an optical film having functions required for the display panel 11 used, such as a contrast refine film (CRF) or a polarizing plate, is desirably selected as appropriate. Therefore, the optical film 14 is not particularly limited. In the present embodiment, the optical film 14 is used as the adjacent layer, but the adjacent layer may be a film having no particular optical properties in some cases. The thickness of the optical film 14 is, for example, about 100 to 500 μm. The thickness may be greater.

The adhesive layer 13 is provided to bond the display panel 11 and the transparent protective member 12 together. Since the adhesive layer 13 need to transmit video images displayed on the display panel 11, it is made of an adhesive material having transparency. Desirably, the adhesive layer 13 has a visible light transmittance of at least 90%. Desirably, the material of the adhesive layer 13 has a refractive index almost equal to that of the material of the transparent protective member 12. For example, a material having a refractive index of 1.4 to 1.6 is desired. The thickness of the adhesive layer 13 is, for example, 25 μm or more and 600 μm or less.

The adhesive layer 13 is required to have high adhesiveness and deformability so that the display panel 11 and the transparent protective member 12 can reliably be bonded together without bubbles formed therebetween. Therefore, desirably, the adhesive layer 13 has an adhesive strength of, for example 1 to 80 N/25 mm. The adhesive strength, as used herein, refers to the force measured in the following manner. Adhesive sheets with a width of 25 mm are respectively attached to glass sheets and then a polyethylene terephthalate (PET) test sheet and a hard-coated PET test sheet are respectively attached onto the adhesive sheets. Then, each of the test sheets is pulled in a direction of 90 degrees from the glass sheet at a tensile speed of 300 mm/min to measure the force required to remove the test sheet from the glass sheet. Furthermore, it is desirable that, as viscoelastic properties, the shear storage elastic modulus be, for example, 1×10⁶ Pa or less (at 23° C.) and the loss tangent (tan δ) be, for example, 0.4 or more (at 23° C.). These viscoelastic properties are the values obtained by dynamic viscoelasticity measurement.

The adhesive layer 13 is provided so that the outer boundary 13a thereof lies within the outer boundary 11a of the display panel 11 and the outer boundary 12a of the transparent protective member 12, but in the case where the peripheral portion of the transparent protective member 12 is, for example, painted black, it is desirable to provide the adhesive layer 13 so that the outer boundary 13a thereof lies beyond the inner boundary of the black-painted region. The peripheral portion of the adhesive layer 13 can be provided in contact with other members without any particular problem. The thickness of the black-painted portion formed in the peripheral portion is desirably 10 μm or less, and more desirably 5 μm or less, in view of the thickness deformability (step absorbability) of the adhesive layer 13. The peripheral portion does not necessarily need to be painted black, and the applied color is not limited. The painted region may be formed by printing.

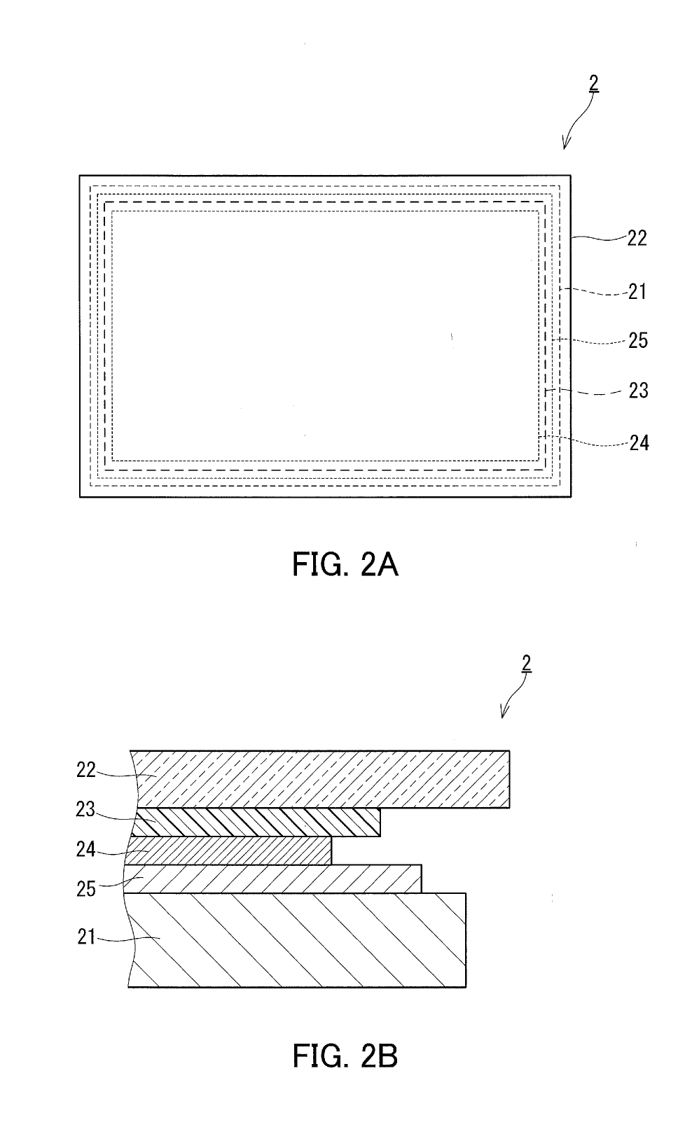

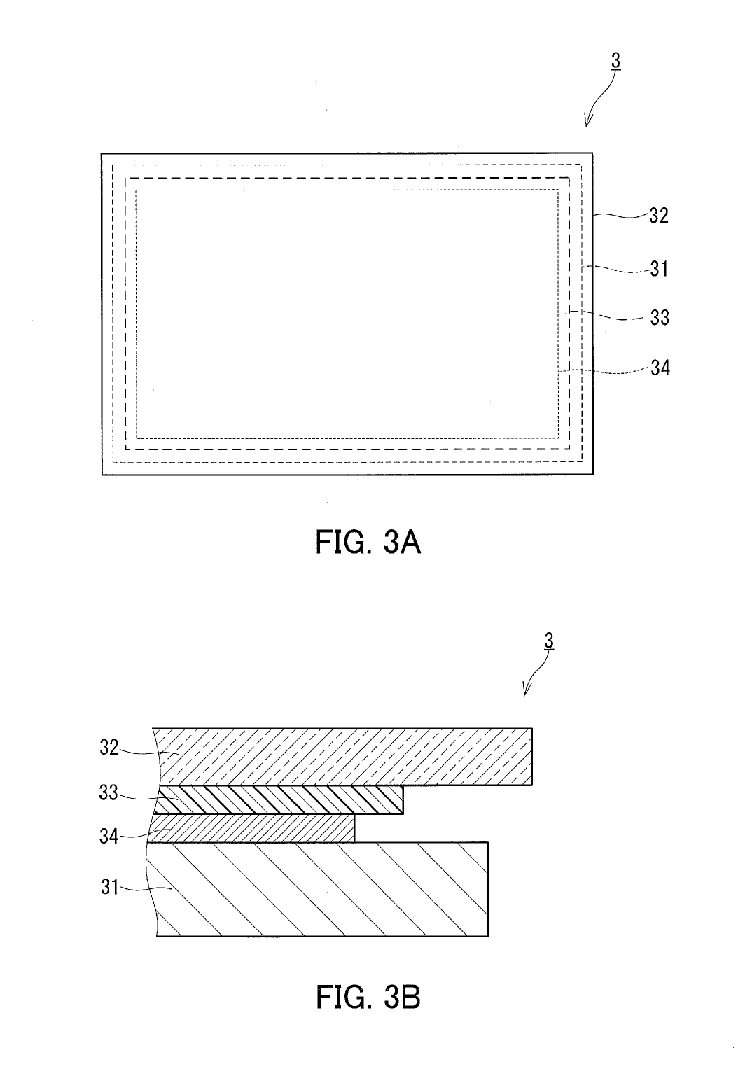

Here, as more specific examples of the display device, FIG. 2A and FIG. 2B show a plasma display device 2 in which the display panel is a PDP 21, and FIG. 3A and FIG. 3B show a liquid crystal display device 3 in which the display panel is an LCD panel 31.

The plasma display device 2 shown in FIG. 2A and FIG. 2B includes the PDP 21 and a cover glass (or a touch panel) 22 that is a transparent protective member for protecting the display surface of the PDP 21. The plasma display device 2 further includes an adhesive layer 23 that is disposed between the PDP 21 and the cover glass 22 so as to bond the PDP 21 and the cover glass 22 together. The plasma display device 2 further includes, between the PDP 21 and the adhesive layer 22, a CRF (adjacent layer) 24 in contact with the adhesive layer 23 and an electromagnetic wave blocking layer 25. The adhesive layer 13 in the display device 1 is applied to the adhesive layer 23. As the PDP 21, the CRF 24, and the electromagnetic wave blocking layer 25, known ones used in typical plasma display devices can be used. In this plasma display device 2, the CRF 24 serves as a layer that forms a step with the adhesive layer 23, and the outer boundary of the adhesive layer 23 extends outwardly beyond the outer boundary of the CRF 24. The effects obtained by the plasma display device 2 configured in this manner are the same as those obtained by the display device 1. The desirable extending length of the adhesive layer 23 is equal to that of the adhesive layer 13 in the display device 1.

The liquid crystal display device 3 shown in FIG. 3A and FIG. 3B includes an LCD panel 31 and a cover glass (or a touch panel) 32 that is a transparent protective member for protecting the display surface of the LCD panel 31. The liquid crystal display device 3 further includes an adhesive layer 33 that is disposed between the LCD panel 31 and the cover glass 32 so as to bond the LCD panel 31 and the cover glass 32 together. The display device 3 further includes, between the LCD panel 31 and the adhesive layer 32, a polarizing plate (adjacent layer) 34 in contact with the adhesive layer 33. In this liquid crystal display device 3, the polarizing plate 34 serves as a layer that forms a step with the adhesive layer 33, and the outer boundary of the adhesive layer 33 extends outwardly beyond the outer boundary of the polarizing plate 34. The effects obtained by the liquid crystal display device 3 configured in this manner are the same as those obtained by the display device 1. The desirable extending length of the adhesive layer 33 is also equal to that of the adhesive layer 13 in the display device 1.

Next, a method for producing a display device according to the present embodiment, in particular, steps of forming an adhesive layer, are described.

A method for producing a display device according to the present embodiment includes the steps of (I) preparing a display panel for displaying images, a transparent protective member for protecting a display surface of the display panel, and a material roll formed by winding in a roll shape an adhesive sheet used to bond the display panel and the transparent protective member together; (II) feeding the adhesive sheet from the material roll and attaching the adhesive sheet to the display panel or the transparent protective member; (III) forming an adjacent layer (for example, an optical film) on the transparent protective member or the display panel to which the adhesive sheet has not been attached in the step (II); and (IV) bonding the display panel or the transparent protective member to which the adhesive sheet has been attached and the transparent protective member or the display panel on which the adjacent layer has been formed so that the adhesive sheet and the adjacent layer are in contact with each other. The adhesive sheet is attached to the display panel or the transparent protective member so that the outer boundary of the adhesive sheet lies beyond the outer boundary of the adjacent layer and within the outer boundary of the display panel and the outer boundary of the transparent protective member, as viewed from the front of the display surface of the display panel.

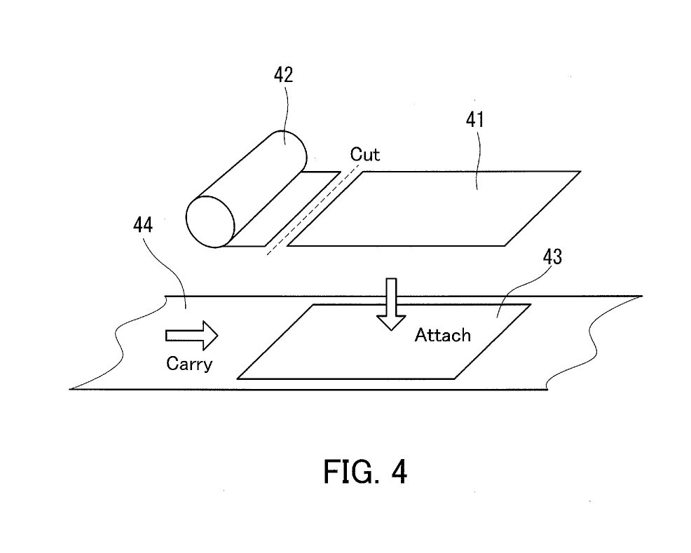

FIG. 4 shows an example of the step (II). In the step (II), a material roll 42 formed by winging an adhesive sheet 41 in a roll shape is used. An object (a display panel or a transparent protective member) 43 to which the adhesive sheet 41 is to be attached is carried, with its adherend surface facing up, by a carrier apparatus 44 such as a conveyer belt. Each time the required length of the adhesive sheet 41 is fed from the material roll 42, it is cut or half-cut in the TD (transverse direction) and attached directly to the object 42 on the carrier apparatus 44. When the adhesive sheet 41 is attached to the display panel or the transparent protective member in this manner, no part of the adhesive sheet 41 is discarded as waste. Therefore, the material yield is much higher than when the conventional technique such as die cutting is used. Furthermore, since this method eliminates the need for die cutting and allows continuous processing, very high productivity can be achieved. In the step (II), the adhesive sheet may be attached to the display panel or the transparent protective member on which another layer has been previously formed, as needed. In this case, the adhesive sheet is attached to the display panel or the transparent protective member with the other layer interposed therebetween.

In the step (III), an optical film or the like serving as the adjacent layer is formed on one of the display panel and the transparent protective member to which the adhesive sheet has not been attached in the step (II). A known technique can be used as a technique for forming the optical film. For example, a technique of attaching a separately produced optical film to the display panel or the transparent protective member using an adhesive material.

In the step (IV), the display panel or the transparent protective member to which the adhesive sheet has been attached and the transparent protective member or the display panel on which the adjacent layer has been formed are bonded together so that the adhesive sheet and the adjacent layer are in contact with each other. When the display panel and the transparent protective member are bonded together, they are positioned so that the outer boundary of the adhesive sheet lies beyond the outer boundary of the adjacent layer and within the outer boundary of the display panel and the outer boundary of the transparent protective member, as viewed from the front of the display surface of the display panel.

As described above, when an adhesive sheet is used to produce an adhesive layer of a display device, the adhesive sheet is more susceptible to defects caused by deformation of its end face due to squeezing and oozing of the adhesive material, as well as defects caused by adhesion of dust, etc. These defects results in failure of adhesion itself (abnormal appearance and quality caused by adhesion failure, delamination, etc.) between the display panel and the transparent protective member. Conventionally, in order to avoid this problem, the edge portion of the adhesive sheet including these defects is not used in products. For example, in the steps of producing the adhesive layer, an adhesive sheet attached to a carrier film (separator film) is die-cut into a predetermined shape for use or an adhesive sheet obtained by die cutting is attached to a carrier film of a larger size for use, so as to remove the defective portions previously and eliminate the adverse effects of the defective portions on the products.

On the other hand, in the case where an adhesive layer is formed in a display device such as a flat screen television or a large screen display, it is desirable, in view of productivity, to produce the adhesive layer by feeding a raw adhesive sheet prepared without being subjected to the conventional die cutting step, that is, the adhesive sheet of the material roll, directly onto the display panel or the transparent protective member. In the present embodiment, the outer boundary of the adhesive layer extends outwardly beyond the outer boundary of the layer adjacent to the adhesive layer (the outer boundary of the optical film in the present embodiment). According to this configuration, even if the adhesive sheet has a defect at its edge portion, the defect is received by the space formed by the step between the outer boundary of the adhesive sheet and the outer boundary of the adjacent layer. Therefore, failure of adhesion itself between the display panel and the transparent protective member does not occur. Thus, it is possible to produce the adhesive layer by feeding the adhesive sheet from the material roll directly onto the display panel or the transparent protective member, as in the production method of the present embodiment. As described above, the display device of the present embodiment can be provided as a display device with high image quality and high reliability by a highly productive method.

In order to obtain the above-described effects more reliably, in the display device, the outer boundary of the adhesive layer extends desirably at least 0.1 mm, more desirably at least 1 mm, and even more desirably at least 3 mm beyond the outer boundary of the adjacent layer. On the other hand, the extending length of the adhesive layer is desirably 5 mm or less in order to prevent the extending portion from sticking to the portion to which the extending portion should not stick (for example, the display panel and a film member other than the adhesive layer) due to warpage and deformation of the transparent protective member that may occur in the bonding step. There is no problem even if the extending length of the adhesive layer is more than 5 mm, as long as the adhesive layer is located within the area of the transparent protective member (as long as the adhesive layer does not extend outwardly beyond the transparent protective member), if no structural problem occurs.

The production method of the present embodiment is characterized in that the adhesive sheet is wound in a roll shape as described above, but the shape of the adhesive sheet is not limited to the roll shape. Instead of the adhesive sheet wound in a roll shape, an adhesive sheet obtained by die cutting also can be used.

In the present embodiment, an optical film is described as an example of the adjacent layer adjacent to the adhesive layer, but the adjacent layer is not limited to this. The adjacent layer may be a layer having other functions as long as the layer is disposed in contact with the adhesive layer and the outer boundary of that layer recedes from the outer boundary of the adhesive layer so as to form a step between the end face of the adhesive layer and the end face of that layer. For example, it is also possible to form a step on the surface of the transparent protective member so as to allow the step portion to serve as the adjacent layer.

In the present embodiment, the example in which the adhesive layer is disposed on the transparent protective member and the optical film as the adjacent layer is disposed on the display panel has been described. However, the display device may be configured so that the adhesive layer is disposed on the display panel and the optical film as the adjacent layer is disposed on the transparent protective member.

### INDUSTRIAL APPLICABILITY

The present invention can be applied to various display devices provided with various types of display panels such as PDPs and LCD panels, and it is particularly useful in large flat screen televisions, etc.

1. A display device comprising:
a display panel for displaying images;
a transparent protective member for protecting a display surface of the display panel;
an adhesive layer that is disposed between the display panel and the transparent protective member so as to bond the display panel and the transparent protective member together; and
an adjacent layer that is disposed adjacent to the adhesive layer and between the display panel and the adhesive layer or between the transparent protective member and the adhesive layer, wherein
an outer boundary of the adhesive layer lies beyond an outer boundary of the adjacent layer and within an outer boundary of the display panel and an outer boundary of the transparent protective member, as viewed from the front of the display surface of the display panel, and
the adhesive layer is in contact only with the layers adjacent thereto.

2. The display device according to claim 1, wherein the outer boundary of the adhesive layer lies at least 0.1 mm beyond the outer boundary of the adjacent layer, as viewed from the front of the display surface of the display panel.

3. The display device according to claim 1, wherein the adjacent layer is formed of an optical film.

4. A method for producing a display device, comprising the steps of:
(I) preparing a display panel for displaying images, a transparent protective member for protecting a display surface of the display panel, and a material roll formed by winding in a roll shape an adhesive sheet used to bond the display panel and the transparent protective member together or the adhesive sheet formed in a predetermined shape;
(II) attaching the adhesive sheet fed from the material roll or the adhesive sheet formed in the predetermined shape to the display panel or the transparent protective member;
(III) forming an adjacent layer on the transparent protective member or the display panel to which the adhesive sheet has not been attached in the step (II); and
(IV) bonding together the display panel or the transparent protective member to which the adhesive sheet has been attached and the transparent protective member or the display panel on which the adjacent layer has been formed so that the adhesive sheet and the adjacent layer are in contact with each other, wherein
the adhesive sheet is attached to the display panel or the transparent protective member so that an outer boundary of the adhesive sheet lies beyond an outer boundary of the adjacent layer and within an outer boundary of the display panel and an outer boundary of the transparent protective member, as viewed from the front of the display surface of the display panel, and that the adhesive sheet is in contact only with the layers adjacent thereto.
